(19) United States
(12) Patent Application Publication
(10) Pub. No.: US 2008/0020549 A1
(43) Pub. Date: Jan. 24, 2008

(54) Method and apparatus for forming an oxide layer on semiconductors

(75) Inventors: Edward Tsidilkovski, Chelmsford, MA (US); Kenneth Steeples, Billerica, MA (US)

Correspondence Address: Kirkpatrick & Lockhart Preston Gates Ellis LLP;(FORMERLY KIRKPATRICK & LOCKHART NICHOLSON GRAHAM), STATE STREET FINANCIAL CENTER, One Lincoln Street, BOSTON, MA, 02111-2950, US

(73) Assignee: QC Solutions, Inc., Billerica, MA (US)

(21) Appl. No.: 11/490,491

(22) Filed: Jul. 20, 2006

(51) Int. Cl. H01L 21/00

(52) U.S. Cl. 438/464

(57) ABSTRACT

A method and apparatus for forming an oxide layer on semiconductors using a combination of ultraviolet rays and heat. The apparatus comprises a chamber having a top surface and a bottom surface and defining a wafer holding cavity; an ultraviolet source at the top surface of said chamber; an infrared source at the bottom surface of the chamber; and an oxygen gas inlet for passing oxygen gas through the chamber. Oxygen gas entering the chamber through the oxygen gas inlet is ionized by ultraviolet rays from the ultraviolet source and reacts with the silicon wafer to create an oxide layer on the silicon wafer in the cavity. Infrared radiation from the infrared source heats the silicon wafer to accelerate the creation of the oxide layer on said silicon wafer.

### FIELD OF INVENTION

The invention relates generally to semiconductor processing and, more specifically, to forming an oxide layer on a semiconductor wafer.

### BACKGROUND FOR THE INVENTION

The method of non-contact resistivity measurement of semiconductor wafers as described in U.S. Pat. No. 5,661,408, is based on the surface photo-voltage effect induced by modulated light that modifies semiconductor surface charge (Q_{S}). Variations of this charge are measured with a capacitively coupled sensor, as previously described in the patent. In order to maintain the electrical neutrality of the wafer, the surface charge (Q_{S}) must be compensated by the charge in the near surface space charge depletion region Q_{SC} (Q_{S}=−Q_{SC}). In the case of a fully depleted space charge region, the Q_{SC} value can be correlated to the semiconductor doping concentration.

The full depletion (inversion) state is a prerequisite for the accurate and reproducible measurement of wafer doping/resistivity. This condition can be achieved in several ways. For n-type silicon, the wafer surface can be subjected to a chemical treatment with KMnO₄ or H₂O₂. For p-type wafers, the surface can be treated with the ROST™ technique described in U.S. Pat. No. 6,803,588. Alternatively, a corona charge of appropriate polarity can be deposited on a wafer surface. Charging with a corona may be used for wafers of both doping types, as described previously. This method is well characterized, well controlled, and can: be used in conjunction with photo-voltage measurement as a feedback to maintain the proper charge state.

The challenge of charging and subsequent measurement of wafer resistivity with this method, especially when using epitaxial wafers, is the requirement to have a good quality, uniform, and thin dielectric layer on a wafer surface that can hold corona charge for several minutes needed for the measurement. The natural choice for this type of film for silicon wafers is silicon dioxide (SiO₂). Such a film creates a better quality (smaller number of defects) interface to the semiconductor. There are several well-developed approaches to grow SiO₂ including high temperature thermal oxidation with O₂ gas or chemical oxidation with H₂O₂ liquid. For thinner oxides <100 Å, the alternative is an ozone (O₃) solution immersion, or a photo-oxidation process utilizing UV light to create reactive oxygen species like ozone and atomic oxygen.

The photo-oxidation process produces high quality thin oxide film at relatively low temperatures. The stoichiometry of the photo-oxide depends on the content of oxygen and water in the reactive atmosphere. The rate of photo-oxidation depends on several parameters: gas and wafer temperature, time of UV exposure, UV light intensity and type of gas used for oxidation (ambient air, dry oxygen, etc.).

What is needed is a quick way of producing the oxide layer on a semiconductor wafer.

### SUMMARY OF THE INVENTION

The invention relates to a method and apparatus for forming an oxide layer on semiconductors using a combination of ultraviolet light and heat.

In one aspect, an apparatus for forming an oxide layer on a silicon wafer is provided. In one embodiment, the apparatus comprises a chamber having a top surface and a bottom surface and defining a wafer holding cavity; an ultraviolet source at the top surface of the chamber; an infrared source at the bottom surface of the chamber; and an oxygen gas inlet for passing oxygen gas through the chamber. Oxygen gas entering the chamber through the oxygen gas inlet is converted to ozone (O₃) gas by ultraviolet rays from the ultraviolet source and the ozone gas then reacts with the silicon wafer to create an oxide layer on the silicon wafer in the cavity. Infrared radiation from the infrared source heats the silicon wafer to accelerate the creation of the oxide layer on the silicon wafer.

In another embodiment, the ultraviolet source in the apparatus further includes a thermostat that controls the temperature of the ultraviolet source. In yet another embodiment, nitrogen gas is passed through the ultraviolet source to control the temperature of the ultraviolet source. In variations of this embodiment, the apparatus further includes a controller regulating the amount of nitrogen gas passing through the ultraviolet source.

In still another embodiment, the apparatus further includes an ultraviolet transparent filter between the ultraviolet source and a silicon wafer located within the chamber. The ultraviolet transparent filter blocks infrared radiation from the infrared source and prevents the radiation from reaching the ultraviolet source. In another embodiment, the apparatus further includes an infrared transparent filter between the infrared source and the silicon wafer located in the chamber. The infrared transparent filter passes infrared radiation and prevents other radiation from reaching the infrared source. The infrared transparent filter also helps to distribute infrared radiation from the infrared source evenly to the wafer.

In yet another embodiment, the apparatus further includes a scrubber in communication with the chamber. The scrubber removes any ozone discharged from the chamber.

In another aspect, a method of forming an oxide layer on a wafer is provided. In one embodiment, the method includes the steps of providing a wafer; directing ultraviolet radiation at oxygen gas passing over the wafer; and heating the wafer. In the process, the oxygen gas is converted to ozone gas by the ultraviolet rays and the ozone gas reacts with the wafer to create an oxide layer on the wafer. The heating of the wafer accelerates the formation of the oxide layer on the wafer.

In a second embodiment, the method further includes the steps of measuring the temperature of an ultraviolet source for the ultraviolet radiation and controlling the temperature of the ultraviolet source by passing nitrogen gas through the ultraviolet source. In variations of the embodiment, controlling the temperature of ultraviolet source is achieved by controlling either the temperature or the flow of the nitrogen gas.

### BRIEF DESCRIPTION OF THE DRAWINGS

The foregoing and other objects, aspects, features, and advantages of the invention will become more apparent and may be better understood by referring to the following description taken in conjunction with the accompanying drawings, in which:

FIG. 1 is a perspective schematic diagram illustrating an apparatus to form an oxide layer on a semiconductor wafer, according to an embodiment of the invention; and

FIG. 2 is a diagram illustrating the corresponding relationship between the temperature of the ultraviolet source and the ultraviolet radiation output.

### DETAILED DESCRIPTION OF THE PREFERRED EMBODIMENTS

The present invention will be more completely understood through the following detailed description, which should be read in conjunction with the attached drawings. In this description, like numbers refer to similar elements within various embodiments of the present invention. Within this detailed description, the claimed invention will be explained with respect to preferred embodiments. However, the skilled artisan will readily appreciate that the methods and systems described herein are merely exemplary and that variations can be made without departing from the spirit and scope of the invention.

In the process of manufacturing semiconductor chips, an essential step is to oxidize the surface of the semiconductor wafer as described above. The invention disclosed herein relates to an apparatus and a method for forming an oxide layer on semiconductor wafer by using a combination of ultraviolet light and heat. In brief overview, a silicon wafer is exposed to ozone gas so that a chemical reaction takes place on the surface of the silicon wafer forming an oxide layer on the surface. Ultraviolet radiation is used to convert oxygen gas to ozone gas, and the silicon wafer is heated in the process to accelerate the chemical reaction.

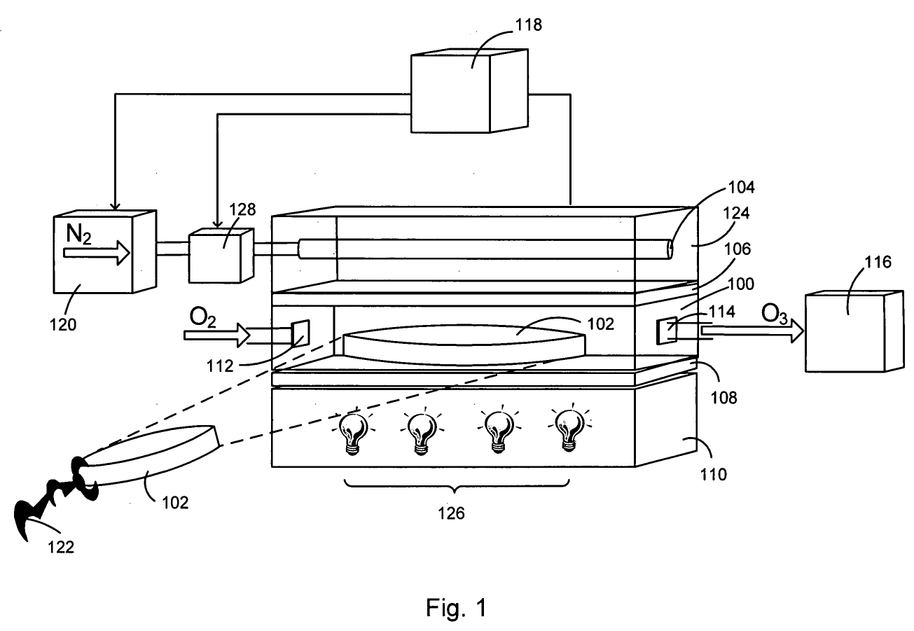

Referring to FIG. 1, a perspective schematic diagram illustrating an apparatus constructed according to an embodiment of the invention is shown. In this embodiment, the apparatus includes a chamber 100 capable of holding a silicon wafer 102. An ultraviolet source 104 is positioned at the top surface of the chamber 100 and an ultraviolet transparent filter 106 is positioned between the ultraviolet source 104 and the location of the wafer 102 when the wafer is located in the chamber 100. An infrared source 110 is positioned at the bottom surface of the chamber 100. An infrared transparent filter 108 is located between the infrared source 110 and the location of the wafer 102 when the wafer is located in the chamber 100. An oxygen gas inlet 112 is positioned on one wall of the chamber 100 for passing oxygen gas through the chamber 100 and an outlet 114 on another wall of the chamber 100 releases the gas to a scrubber 116. A nitrogen gas source 120 is in communication with the ultraviolet source 104. A controller 118 is in communication with the ultraviolet source 104 and the nitrogen gas source 120. The controller 118 controls the flow of nitrogen gas through the ultraviolet source 104. Optionally, a refrigeration unit 128 is positioned between the nitrogen gas source 120 and the ultraviolet source 104 and in communication with the controller 118. In this embodiment, the controller controls not only the flow of gas through the ultraviolet source, but also the temperature of the gas.

In operation, a silicon wafer 102 is first positioned in the chamber 100 by a robotic arm 122. The chamber 100 is then sealed except for the oxygen gas inlet 112 and the outlet 114. Oxygen gas enters the chamber 114 through the oxygen gas inlet 112. Once in the chamber 112, oxygen gas is ionized by ultraviolet radiation from the ultraviolet source 104 to form ozone. As ozone gas fills up the chamber 100 and surrounds the silicon wafer 102, a chemical reaction takes place on the surface of the silicon wafer 102. The reaction forms an oxide layer (not illustrated) on the surface of the silicon wafer 102. During the process, the silicon wafer 102 is simultaneously heated by the infrared source 110 at the bottom of the chamber 100 to accelerate the formation of the oxide layer.

To prevent infrared rays from reaching the ultraviolet source 104 and heating it, the ultraviolet transparent filter 106, transparent substantially only to ultraviolet radiation, is positioned between the chamber 100 and the ultraviolet source 104. Similarly, the infrared transparent filter 108, transparent only to infrared rays, blocks all ultraviolet radiation and prevents the radiation from reaching the infrared source 110. In one embodiment, the infrared source 110 is a set of infrared lamps 126, which is a strong infrared source. Here, the infrared transparent filter 108 also serves as a heat conductor that helps to distribute the heat from the multiple lamps 126 evenly on the silicon wafer 102.

As illustrated in FIG. 1, the scrubber 116 is connected to the outlet 114 on the wall of the chamber 100. As the chemical reaction forms the oxide layer on the silicon wafer 102, excessive ozone gas containing highly reactive byproducts of the reaction are removed through the outlet 114 by the scrubber 116, which then converts to ozone gas to oxygen.

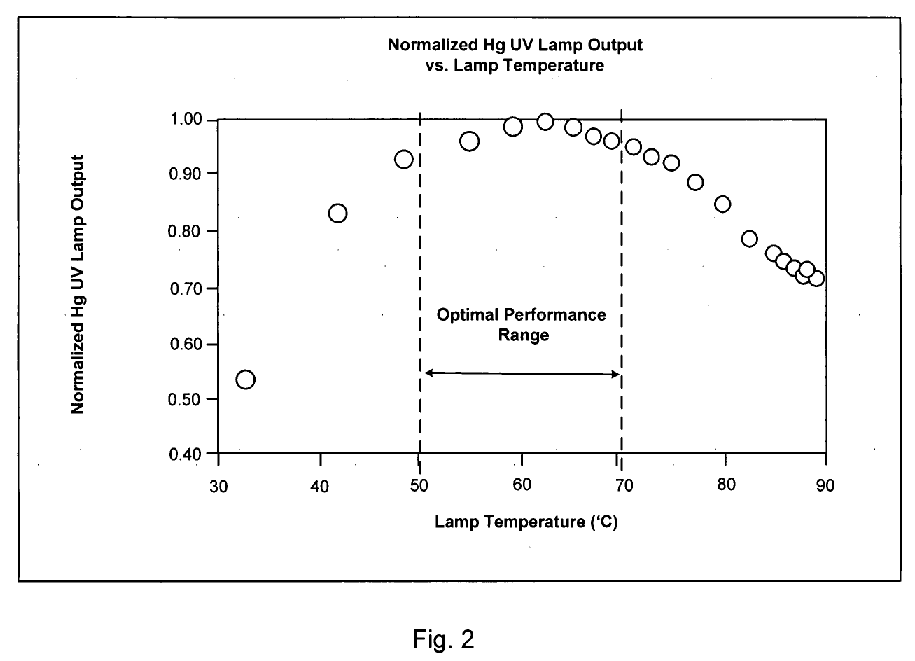

As illustrated in FIG. 2, the optimal performance range for the ultraviolet source used in this embodiment in terms of radiation output is when the temperature of the ultraviolet source is between 50° C. and 70° C. There is a significant drop in radiation output when the ultraviolet source is above 70° C. or below 50° C. In one embodiment, the ultraviolet source is a Model UVJS169 ultraviolet lamp manufactured by Jelight Company Inc. (Irvine, Calif.).

The ultraviolet source may overheat as the process carries on. In one embodiment, the ultraviolet source is a tubular ultraviolet lamp located in a nitrogen gas chamber 124 as shown in FIG. 1. Nitrogen gas is flowed from a nitrogen gas source 120 through the nitrogen gas chamber 124 to keep the ultraviolet source 104 cool. A controller 118 detects the temperature of the ultraviolet source 104 and adjusts the nitrogen gas flow accordingly. If the temperature of the ultraviolet source 104 arises, the controller 118 increases the nitrogen gas flow from the nitrogen gas source 120. Alternatively, the nitrogen gas from the nitrogen gas source 120 is passed through a refrigeration unit 128 before entering the nitrogen gas chamber 124, and the controller 118 sets the temperature of the refrigeration unit 128 to keep the nitrogen gas cool, and the flow rate to keep the ultraviolet source cool.

The method of forming an oxide layer on a silicon wafer involves a chemical reaction of the silicon wafer and ozone gas. To start the reaction, the silicon wafer is moved by a robotic arm into the chamber where the silicon wafer is heated to an optimal temperature at which the chemical reaction can be most efficiently carried out. In one embodiment, the heating is achieved by exposing the silicon wafer under infrared rays from multiple infrared lamps (see FIG. 1). At the same time, ozone gas is produced by pumping oxygen gas into the chamber and subjecting the oxygen gas to ultraviolet radiation. When there is enough ozone gas in the chamber, the chemical reaction takes place and an oxide layer is formed on the surface of the silicon wafer. Excessive ozone gas and other highly reactive byproducts of the chemical reaction are then removed and processed by a scrubber connected to the chamber.

Variations, modifications, and other implementations of what is described herein will occur to those of ordinary skill in the art without departing from the spirit and scope of the invention as claimed. Accordingly, the invention is to be defined not by the preceding illustrative description but instead by the spirit and scope of the following claims.

What is claimed is:

1. An apparatus for forming an oxide layer on a silicon wafer comprising:
a chamber having a top surface and a bottom surface and defining a wafer holding cavity;
an ultraviolet source at said top surface of said chamber;
an infrared source at said bottom surface of said chamber; and
an oxygen gas inlet for passing oxygen gas through said chamber,
wherein oxygen gas entering said chamber through said oxygen gas inlet is converted to ozone gas by ultraviolet rays from said ultraviolet source and reacts with said silicon wafer to create an oxide layer on said silicon wafer in said cavity, and
wherein infrared radiation from said infrared source heats said silicon wafer to accelerate the creation of said oxide layer on said silicon wafer.

2. The apparatus of claim 1 wherein said ultraviolet source further comprises a thermostat wherein said thermostat controls the temperature of said ultraviolet source.

3. The apparatus of claim 1 wherein nitrogen gas is passed through said ultraviolet source to control the temperature of said ultraviolet source.

4. The apparatus of claim 1 wherein said ultraviolet source further comprises a controller controlling the amount of nitrogen gas passing through said ultraviolet source.

5. The apparatus of claim 1 further comprising an ultraviolet transparent filter between said ultraviolet source and said silicon wafer wherein infrared radiation from said infrared source is blocked by said ultraviolet transparent filter from reaching said ultraviolet source.

6. The apparatus of claim 1 further comprising a scrubber in communication with said chamber wherein said scrubber removes oxygen ions discharged from said chamber.

7. The apparatus of claim 1 wherein said infrared source further comprises a plurality of infrared lamps.

8. The apparatus of claim 1 further comprising an infrared transparent filter between said infrared source and said silicon wafer.

9. The apparatus of claim 8 wherein said infrared transparent filter helps to distribute infrared radiation from said infrared source evenly on said wafer.

10. The apparatus of claim 8 wherein ultraviolet rays from said ultraviolet source is blocked by said IR transparent filter from reaching said infrared source.

11. A method of forming an oxide layer on a wafer comprising the steps of:
providing a wafer;
directing ultraviolet radiation at oxygen gas passing over said wafer; and
heating said wafer,
wherein said oxygen gas is converted to ozone gas by said ultraviolet rays and reacts with said wafer to create an oxide layer on said wafer, and
wherein the heating of said wafer accelerates the formation of said oxide layer on said wafer.

12. The method of claim 11 further comprising the step of measuring the temperature of an ultraviolet source for said ultraviolet radiation.

13. The method of claim 12 further comprising the step of controlling the temperature of said ultraviolet source.

14. The method of claim 13 further comprising the step of passing nitrogen gas through said ultraviolet source.

15. The method of claim 14 further comprising the step of controlling the temperature of said nitrogen gas.

16. The method of claim 14 further comprising the step of controlling the flow of said nitrogen gas.

17. The method of claim 11 further comprising the step of scrubbing said ozone gas.
